(19) United States
(12) Patent Application Publication
(10) Pub. No.: US 2011/0260027 A1
(43) Pub. Date: Oct. 27, 2011

(54) SOLAR PANEL MOUNTING ASSEMBLY WITH LOCKING CAP

(75) Inventor: RICHARD ROBERT FARNHAM, JR., CONCORD, NC (US)

(73) Assignee: DAETWYLER-CLEAN ENERGY LLC, HUNTERSVILLE, NC (US)

(21) Appl. No.: 13/091,434

(22) Filed: Apr. 21, 2011

Related U.S. Application Data
(60) Provisional application No. 61/327,271, filed on Apr. 23, 2010.

(51) Int. Cl. H01L 23/12

(52) U.S. Cl. 248/309.1

(57) ABSTRACT

A solar panel mounting assembly including a bracket having a base, a central member extending from the base defining a channel opening in a direction away from the base, and first and second coplanar rails carried on the central member and spaced apart from the base, and a locking cap that lockingly engages within the channel including first and second spaced legs and a head that overhangs a portion of each of the first and second rails. A solar panel mounting system including a solar panel, bracket and locking cap.

### CROSS-REFERENCE TO RELATED APPLICATION

This application claims priority to Provisional Application No. 61/327,271 filed Apr. 23, 2010 and entitled “SOLAR PANEL MOUNTING BRACKET WITH LOCKING CAP”, the contents of which are incorporated by reference herein.

### BACKGROUND

Although an individual solar panel may have any desired shape, common shapes include rectangular panels chosen for their ease of both manufacture and installation. These rectangular panels are commonly framed, such as with aluminum, to protect the panel edges from delamination and damage, as well as to provide structure for securing the panel within a mounting system. Panels are typically supported from beneath or from the sides in order to keep the energy-collecting portion of the panel free from obstructions. As the panels and the associated electronics comprise the majority of the cost of the photovoltaic systems, and as installation and repair labor can additionally be costly, it is desirable to provide a mounting system that not only supports solar panels without obstruction, but also prevents the panels from being removed from the system without great effort.

### BRIEF SUMMARY

In one aspect, the present invention provides solar panel mounting assemblies.

In another aspect, the assemblies support the panels in a secure manner without obstructing the energy-collecting surface of the panels.

In another aspect, the assemblies include a bracket and locking cap configured to engage the bracket to capture a portion of a solar panel.

In another aspect, the assemblies lock a panel in place in a secure manner that resists at least upward pulling forces.

In another aspect, the assemblies further include channels for routing and maintaining solar panel associated cabling.

To achieve the foregoing and other aspects, in one embodiment a solar panel mounting assembly is provided including a bracket having a base, a central member extending from the base defining a channel opening in a direction away from the base, and first and second coplanar rails carried on the central member and spaced apart from the base, and a locking cap configured to lockingly engage within the channel having first and second spaced legs and a head overhanging a portion of each of the first and second rails when the locking cap is engaged in the channel.

In a further embodiment, the head, the first and second rails, and the base are coplanar.

In a further embodiment, the central member includes teeth on inner walls of the channel configured to engage teeth on outer surfaces of the first and second legs when the locking cap is engaged in the channel.

In a further embodiment, the teeth of the central member are angled in a direction of the base and the teeth of the locking cap are angled in a direction of the head.

In a further embodiment, the first and second rails and the base extend laterally from a vertical axis of the channel and the channel spaces apart the first and second rails.

In a further embodiment, the first and second rails and the head define channels therebetween for capturing an edge of a solar panel.

In a further embodiment, the first and second legs of the locking cap are spaced apart a distance about corresponding to a width of the channel.

In a further embodiment, the bracket is an elongate extrusion.

In a further embodiment, the head of the locking cap is separable from the first and second legs and adjustably secured thereto by a fastener for adjusting a distance between the head and the first and second rails.

In another embodiment, a solar panel mounting assembly is provided herein including a unitary bracket having a base, a central member extending from the base defining a channel opening in a direction away from the base, and first and second coplanar rails carried on the central member and spaced apart from the base, the bracket being symmetrical about a vertical axis through the channel in a direction perpendicular to the first and second rails, and a locking cap configured to lockingly engage within the channel and having first and second spaced legs and a head overhanging a portion of each of the first and second rails when the locking cap is engaged in the channel.

In a further embodiment, the central member includes teeth on inner walls of the channel configured to engage teeth on outer surfaces of the first and second legs when the locking cap is engaged in the channel.

In a further embodiment, the first and second legs of the locking cap are spaced apart a distance about corresponding to a width of the channel.

In a further embodiment, the head of the locking cap is separable from the first and second legs and adjustably secured thereto by a fastener received in the direction along the vertical axis for adjusting a distance between the head and the first and second rails.

In another embodiment, a solar panel mounting system is provided herein including a bracket having a base, a central member extending from the base defining a channel opening in a direction away from the base, and first and second coplanar rails carried on the central member and spaced apart from the base, a locking cap configured to lockingly engage within the channel having first and second spaced legs and a head overhanging a portion of each of the first and second rails, and a solar panel captured within a space between one of the first and second rails and the head of the locking cap.

### BRIEF DESCRIPTION OF THE DRAWINGS

Features, aspects and advantages of the present invention are better understood when the following detailed description of the invention is read with reference to the accompanying drawings, in which:

FIG. 1 is a perspective view of a solar panel mounting assembly in accordance with one embodiment;

FIG. 2 is a side elevation view of the assembly of FIG. 1;

FIG. 3 is an environmental view showing the assembly of FIG. 1 installed in a system;

FIG. 4 is a perspective view of another embodiment of a solar panel mounting assembly;

FIG. 5 is a perspective view of the assembly of FIG. 4 shown the components in the engaged configuration;

FIG. 6 is a side elevation view of the assembly of FIG. 4 showing the components in the engaged configuration;

FIG. 7 is an isolated perspective view of the locking cap of the assembly shown in FIG. 4; and

FIG. 8 is an isolated perspective view of the bracket of the assembly shown in FIG. 4.

### DETAILED DESCRIPTION

The present invention will now be described more fully hereinafter with reference to the accompanying drawings in which exemplary embodiments of the invention are shown. However, the invention may be embodied in many different forms and should not be construed as limited to the representative embodiments set forth herein. The exemplary embodiments are provided so that this disclosure will be both thorough and complete, and will fully convey the scope of the invention and enable one of ordinary skill in the art to make, use and practice the invention.

Referring to the figures, solar panel mounting assemblies and solar panel systems for mounting solar panels are shown. Although shown primarily as unitary components throughout the figures, it is envisioned that the components of the assemblies may be constructed from pieces. Materials for constructing the components of the assemblies can include lightweight, strong, corrosion-resistant materials capable of being extruded, for example aluminum. Although not shown in the figures, the assembly embodiments can be secured to supporting surfaces or other structure using conventional fasteners, for example screws or bolts, received through openings defined through components, for example the base portion of the brackets. In another example, the assemblies can be clamped or welded to supporting structures.

The assembly embodiments hold a solar panel in an elevated position and in a secure manner that resists at least upward pulling forces on the panel. Edge portions of the panel are captured in channels of the assemblies and locked in place with corresponding locking caps that prevent the panels from being removed from the system without great effort. In an exemplary application, one or more edges of a solar panel are captured by assemblies and secured in place using a plurality of locking caps, for example at least two locking caps positioned along each captured edge of the panel. Solar panels can be captured on multiple slides to prevent panels from being slid out of their channels. Although not shown, assemblies can also include end pieces, corner pieces or stops for preventing lateral movement between the panels and channels. In one embodiment, removal of a locking cap from its channel requires destruction or deformation of the locking cap.

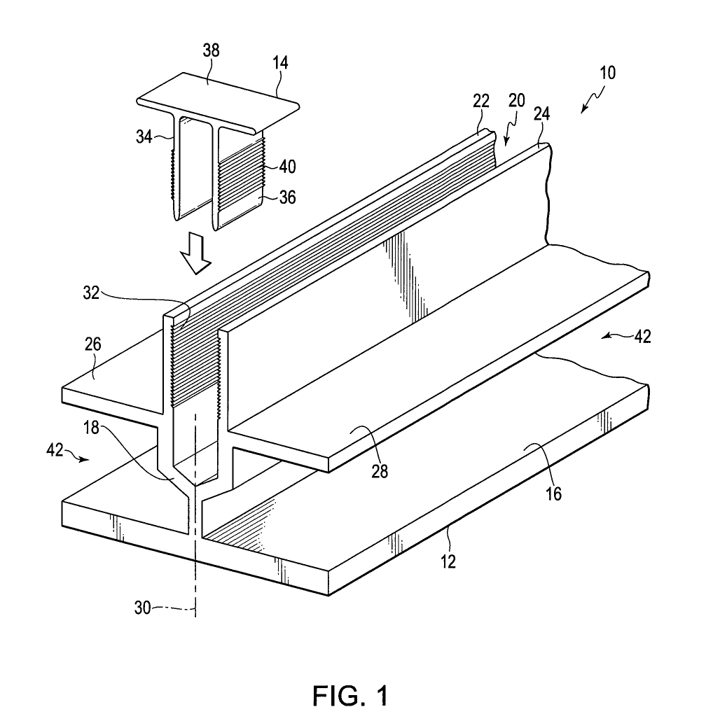

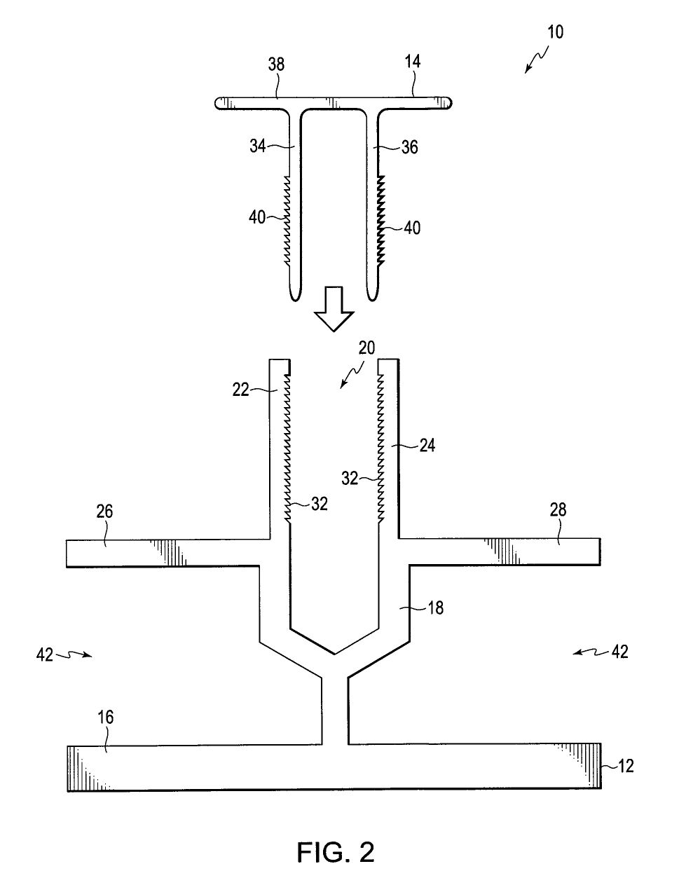

Referring to FIGS. 1-2, a first embodiment of a solar panel mounting assembly is shown generally at reference numeral 10. Assembly 10 generally includes bracket 12 and corresponding locking cap 14 for cooperatively supporting and capturing a solar panel about its edge portion and in an elevated position.

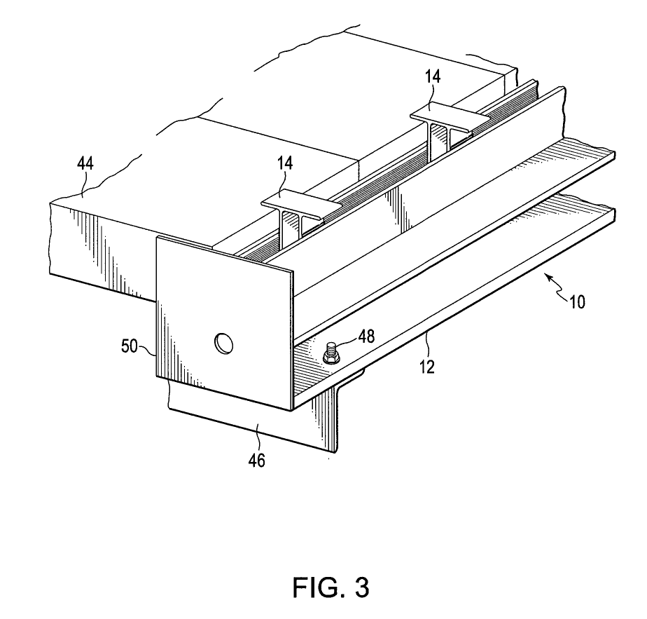

Bracket 12 includes generally planar base 16 for stably supporting assembly 10. Shown in FIG. 3, assembly 10 can be secured in place by providing fasteners through or attaching hardware to base 16 to underlying supporting surface or structure. Extending vertically in a direction away from a major face of base 16 is central portion 18 defining channel 20 that opens in the direction away from base 16. For example, central member 18 can be a generally U-shaped member defining a closed bottom and sidewalls 22, 24 extending in the direction away from base 16. First and second rails 26, 28 are carried on central member 18 and are spaced apart from base 16. As shown, rails 26, 28 are arranged substantially parallel to base 16 and spaced apart therefrom to define channels 42 between the rails and the base, for example for routing and maintaining solar panel associated cabling.

Bracket 12 is symmetrical about vertical axis 30 defined through channel 20 oriented perpendicular to base 16 and rails 26, 28. Base 16 and rails 26, 28 extend laterally from axis 30 about the same distance. Rails 26, 28 are spaced apart by the width of channel 20 and are coplanar and parallel to base 16. Sidewall 22 and rail 26 cooperatively define a seating surface on one side of bracket 12 for an edge portion of a first solar panel. Sidewall 24 and rail 28 cooperatively define a seating surface on the other side of bracket 12 for an edge portion of a second solar panel. Sidewalls 22, 24 extend vertically beyond rails 26, 28 in the direction away from base 12 to prevent captured solar panels from moving laterally in the directions toward channel 20.

The inner surfaces of channel 20 defined by sidewalls 22, 24 include teeth 32 coextensive with the length of bracket 12 that extend to a depth within channel 20 and lockingly engage corresponding teeth 40 on locking cap 14. Teeth 32 can be angled in the direction toward base 16. Channel 20 has a predetermined width corresponding to about the width of spaced legs 34, 36 of locking cap 14. Channel 20 may also serve as a cable routing channel.

Locking cap 14 generally includes spaced apart legs 34, 36 and head 38. Legs 34, 36 include teeth 40 on their outer faces that engage teeth 32 within channel 20 when locking cap 14 is engaged in channel 20. Teeth 40 can be angled in the direction toward head 38 such that teeth 40 can be forced past teeth 32 in the downward direction toward base 16, but cannot be pulled upward past teeth 32 in the direction away from base 16. In one embodiment, removal of locking cap 14 from engagement in channel 20 requires destruction or deformation of locking cap 14 such that a solar panel cannot be removed without great effort, providing secure mounting and guarding against panel theft.

Locking cap 14 can be engaged in channel 20 by applying downward force on head 38 in the direction toward base 16 and slightly urging legs 34, 36 together. When engaged in channel 20, head 38 extends past central member 18 in the direction of rails 26, 28 such that the head overhangs portions of the rails to capture an edge portion of a solar panel between the rail and its respective overhanging head portion.

Referring to FIG. 3, assembly 10 is shown installed in a system and capturing a solar panel 44 between bracket 12 and locking caps 14. Assembly 10 is supported on structure 46 and secured thereto by fastener 48 received through base 16. End piece 50 attached to assembly 10 prevents solar panel 44 from being slid from its channel along the longitudinal axis of bracket 12. Locking caps 14 are advanced within channel 20 to a depth that head 38 contacts the top surface of panel 44. A plurality of locking caps 14 can be used to secure a single panel or a single locking cap per panel side.

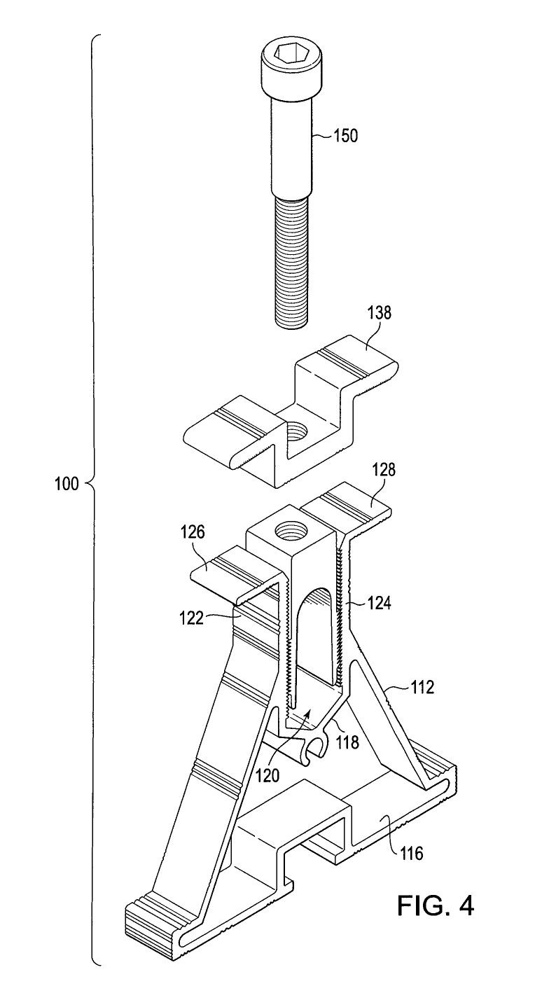

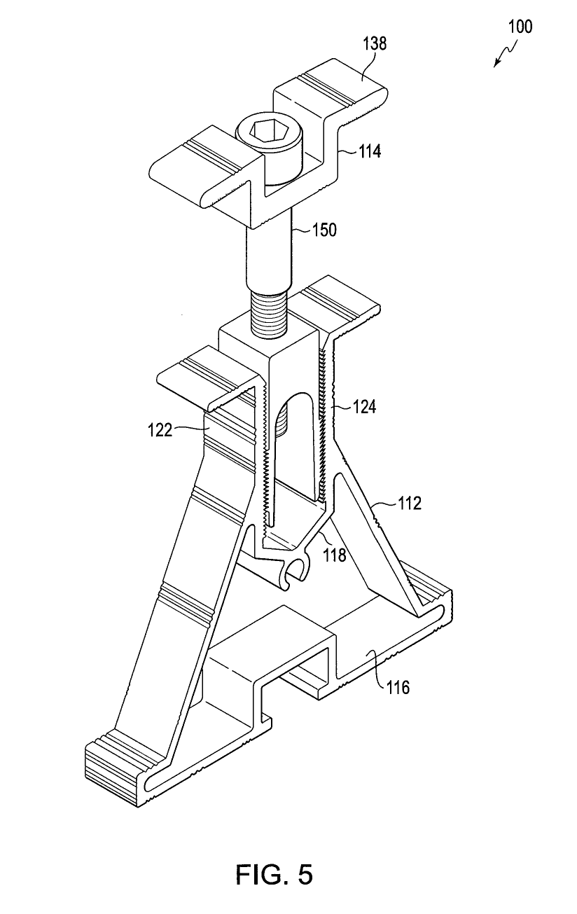

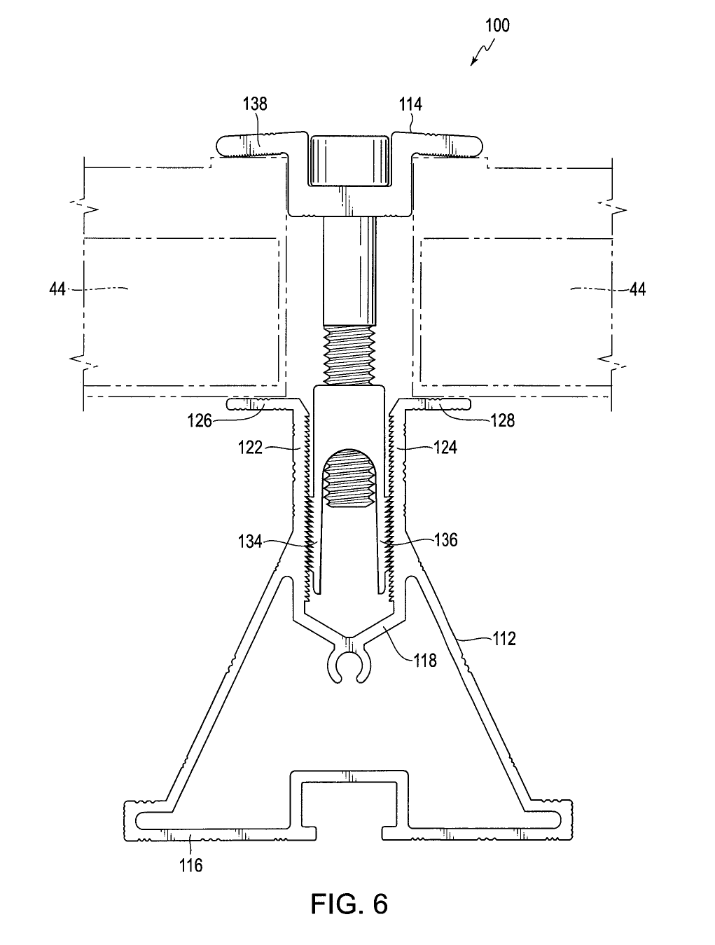

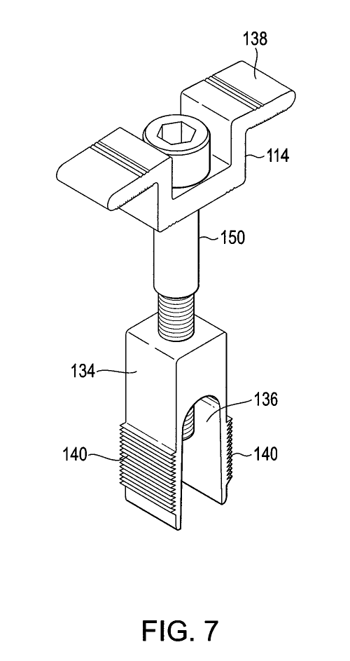

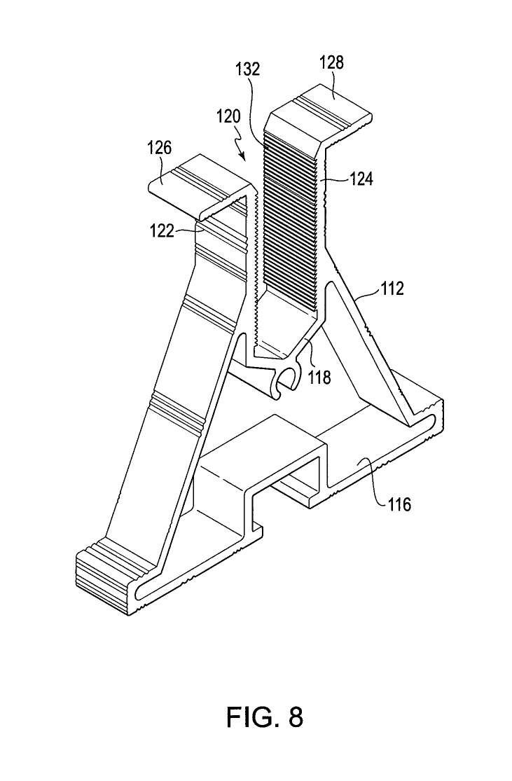

Referring to FIGS. 4-8, another embodiment of a solar panel mounting assembly is shown generally at 100. Assembly 100 generally includes bracket 112 and corresponding locking cap 114 for cooperatively supporting and capturing a solar panel about its edge portion and in an elevated position.

Bracket 112 has a generally triangular shape including base 116 for stably supporting assembly 100. Although not shown, assembly 100 can be secured in place by providing fasteners through or attaching hardware to base 116 to underlying supporting surface or structure. Extending vertically in a direction away from a major face of base 116 is central portion 118 defining channel 120 that opens in the direction away from base 116. For example, central member 118 can be a generally U-shaped member defining a closed bottom and sidewalls 122, 124 extending in the direction away from base 116. First and second rails 126, 128 are carried on central member 118 and are spaced apart from base 116. As shown, rails 126, 128 are arranged substantially parallel to base 116 and spaced apart therefrom.

Bracket 112 is symmetrical about vertical axis defined through channel 120 oriented perpendicular to base 116 and rails 126, 128. Rails 126, 128 are spaced apart by the width of channel 120 and are coplanar and parallel to base 116. Rail 126 defines a seating surface on one side of bracket 112 for an edge portion of a first solar panel. Rail 128 defines a seating surface on the other side of bracket 112 for an edge portion of a second solar panel.

The inner surfaces of channel 120 defined by sidewalls 122, 124 includes teeth 132 coextensive with the length of bracket 112 that extend to a depth within channel 120 and lockingly engage corresponding teeth 140 on locking cap 114. Teeth 132 can be angled in the direction toward base 116. Channel 120 has a predetermined width corresponding to about the width of spaced legs 134, 136 of locking cap 114. Channel 120 may also serve as a cable routing channel.

Locking cap 114 generally includes spaced apart legs 134, 136 and head 138. Legs 134, 136 include teeth 140 on their outer faces that engage teeth 132 within channel 120 when locking cap 114 is engaged in channel 120. Teeth 140 can be angled in the direction toward head 138 such that teeth 140 can be forced past teeth 132 in the downward direction toward base 116, but cannot be pulled upward past teeth 132 in the direction away from base 116.

Head 138 of locking cap 114 is adjustably attached to the leg-carrying portion by threaded fastener 150 that permits adjustment of the distance between head 138 and the leg-carrying portion, and consequentially head 138 and rails 126, 128 when locking cap 114 is engaged in channel 120. The ability to adjust head 138 relative to rails 150 allows assembly 100 to accommodate various solar panel thicknesses and allows a solar panel to be removed from capture without destruction or deformation of locking cap 114. For example, a solar panel can be removed from capture by withdrawing fastener 150 from locking cap 114 to move head 138 away from base 116. Head 138 may be moved upward a distance to clear the solar panel or sufficient to allow head 138 to be rotated 90 degrees to clear the panel. To tighten head 138 against a panel seated on is rail, fastener 150 is advanced in head 138 and the leg-carrying portion.

Locking cap 114 can be engaged in channel 120 by applying downward force on head 138 or the leg-carrying portion in the direction toward base 116 and slightly urging legs 134, 136 together. When engaged in channel 120, head 138 extends past central member 118 in the direction of rails 126, 128 such that the head overhangs portions of the rails to capture an edge portion of a solar panel between the rail and its respective overhanging head portion.

While various embodiments of solar panel mounting assemblies and mounting systems have been described with reference to specific embodiments and examples, it is envisioned that various details of the invention may be changed without departing from the scope of the invention. Furthermore, the foregoing description of the preferred embodiments of the invention and best mode for practicing the invention are provided for the purpose of illustration only and not for the purpose of limitation.

What is claimed is:

1. A solar panel mounting assembly, comprising:
a bracket comprising a base, a central member extending from the base defining a channel opening in a direction away from the base, and first and second coplanar rails carried on the central member and spaced apart from the base; and
a locking cap configured to lockingly engage within the channel, the locking cap comprising first and second spaced legs and a head overhanging a portion of each of the first and second rails when the locking cap is engaged in the channel.

2. The assembly according to claim 1, wherein the head, the first and second rails, and the base are coplanar.

3. The assembly according to claim 1, wherein the central member comprises teeth on inner walls of the channel configured to engage teeth on outer surfaces of the first and second legs when the locking cap is engaged in the channel.

4. The assembly according to claim 3, wherein the teeth of the central member are angled in a direction of the base and the teeth of the locking cap are angled in a direction of the head.

5. The assembly according to claim 1, wherein the first and second rails and the base extend laterally from a vertical axis of the channel.

6. The assembly according to claim 1, wherein the channel spaces apart the first and second rails.

7. The assembly according to claim 1, wherein the first and second rails and the head define channels therebetween for capturing an edge of a solar panel.

8. The assembly according to claim 1, wherein the first and second legs of the locking cap are spaced apart a distance about corresponding to a width of the channel.

9. The assembly according to claim 1, wherein the bracket is an elongate extrusion.

10. The assembly according to claim 1, wherein the head of the locking cap is separable from the first and second legs and adjustably secured thereto by a fastener for adjusting a distance between the head and the first and second rails.

11. A solar panel mounting assembly, comprising:
a unitary bracket comprising a base, a central member extending from the base defining a channel opening in a direction away from the base, and first and second spaced coplanar rails carried on the central member and spaced apart from the base, the bracket being symmetrical about a vertical axis through the channel in a direction perpendicular to the first and second rails; and
a locking cap configured to lockingly engage within the channel, the locking cap comprising first and second spaced legs and a head overhanging a portion of each of the first and second rails when the locking cap is engaged in the channel.

12. The assembly according to claim 11, wherein the central member comprises teeth on inner walls of the channel configured to engage teeth on outer surfaces of the first and second legs when the locking cap is engaged in the channel.

13. The assembly according to claim 11, wherein the first and second legs of the locking cap are spaced apart a distance about corresponding to a width of the channel.

14. The assembly according to claim 11, wherein the head of the locking cap is separable from the first and second legs and adjustably secured thereto by a fastener received in the direction along the vertical axis for adjusting a distance between the head and the first and second rails.

15. A solar panel mounting system, comprising:
a bracket comprising a base, a central member extending from the base defining a channel opening in a direction away from the base, and first and second coplanar rails carried on the central member and spaced apart from the base;
a locking cap configured to lockingly engage within the channel, the locking cap comprising first and second spaced legs and a head overhanging a portion of each of the first and second rails; and
a solar panel captured within a space between one of the first and second rails and the head of the locking cap.

16. The system according to claim 15, wherein the bracket is symmetrical about a vertical axis through the channel in a direction perpendicular to the first and second rails.

17. The system according to claim 15, wherein the central member comprises teeth on inner walls of the channel configured to engage teeth on outer surfaces of the first and second legs when the locking cap is engaged in the channel.

18. The system according to claim 15, wherein the head of the locking cap is separable from the first and second legs and adjustably secured thereto by a fastener for adjusting a distance between the head and the first and second rails.
